(19) United States
(12) Patent Application Publication
(10) Pub. No.: US 2026/0105209 A1
(43) Pub. Date: Apr. 16, 2026

(54) METHOD, DEVICE, TERMINAL AND MEDIUM FOR CONSTRUCTING DIGITAL TWIN MODEL OF HINGED OBJECT

(71) Applicant: SHENZHEN UNIVERSITY, Shenzhen (CN)

(72) Inventors: Ruizhen HU, Shenzhen (CN); Ligang LIU, Shenzhen (CN); Junfu GUO, Shenzhen (CN)

(73) Assignee: SHENZHEN UNIVERSITY, Shenzhen (CN)

(21) Appl. No.: 18/964,013

(22) Filed: Nov. 29, 2024

(30) Foreign Application Priority Data
Oct. 15, 2024 (CN) 202411439048.2

(51) Int. Cl. G06F 30/17; G06F 30/23; G06F 30/27

(52) U.S. Cl. CPC G06F 30/17; G06F 30/23; G06F 30/27

(57) ABSTRACT

A method, device, terminal and medium for reconstructing surface from point clouds based on parametric representation are provided. The method includes: constructing a 3D-GS model in an initial state by using a first multi-view image set of the hinged object in the initial state; identifying an initial movable Gaussian model based on the deformed 3D-GS model predicted by a deformation network; realizing a complete self-supervised optimization of the deformation network based on a second multi-view image set and a deformed model of the hinged object in an end state; jointly optimizing the 3D-GS model, the target movable Gaussian model obtained by re-dividing the initial movable Gaussian model, and the target hinge motion parameters obtained by applying estimated initial hinge motion parameters to the initial movable Gaussian model to optimize the motion parameters, to construct a digital twin of the hinged object.

### CROSS-REFERENCE TO RELATED APPLICATIONS

This application claims priority to Chinese Patent Application No. 202411439048.2, filed on Oct. 15, 2024, the content of all of which is incorporated herein by reference.

### FIELD

The present disclosure relates to the technical field of digital twin model construction, in particular to a method, a device, a terminal and a medium for constructing a digital twin model of a hinged object.

### BACKGROUND

At present, it often plays an important role in robotics, analog simulation, animation production and other fields to construct a digital twin model of hinged objects, accurately reconstruct the digital twin model and estimate the hinge logic.

However, most of the traditional modeling methods of hinged objects rely on prior knowledge, which requires a large quantity of labeled three-dimensional (3D) data as pre-training materials, which consumes a lot of manpower and material resources. Moreover, when the hinged object to be reconstructed is not in the pre-training data set, it may not be possible to estimate the correct hinge logic, and the existing pure self-supervised algorithms use Neural Radiance Field (NeRF) for reconstruction. Its unified optimization method leads to that the correctness of the results strongly depends on the initialization of parameters, which leads to a high error rate. The traditional 3D Gaussian algorithm for reconstructing dynamic scenes cannot estimate the hinge logic, which leads to the inability to accurately interpolate the motion state of the object under sparse state input.

For example, in the field of hinged object reconstruction, a way to reconstruct the surface from a series of point clouds is existing, but the way has a limitation of using a unified surface to represent the hinged object, and the way to reconstruct the hinged object at a part level also has a problem of being highly dependent on a density of frames. The Gaussian motion process between frames cannot be accurately predicted when the frames are sparse. 3D Gaussian Splatting (3D-GS) technology can be used to reconstruct organic hinged objects, such as humans, body parts and animals. However, the movements allowed by the objects are usually very complicated in structure, and connection topology and a quantity of degrees of freedom (DOF) of joints is relatively large, which leads to the increase of complexity of construction. Most previous work on digital twin construction of hinged objects focused on the regeneration or construction of 3D geometric representations of hinged objects, which involves estimating hinge parameters or functions to animate hinged objects to different hinge states, which usually is a grid-based hinged object representation. However, the grid-based hinged object representation has relatively low geometric fidelity and visual realism. In one aspect, at present, reconstruction by supervised learning usually consumes a large number of 3D data sets with hinge information annotations, which also limits the generalization ability of unseen object categories. Furthermore, in the self-supervised work with RGB observations as input, NeRF is used as the intermediate representation, and a mesh model with compromise in geometry and appearance accuracy is output, but the self-supervised work shows instability and suboptimal problems in the optimization process. In another aspect, the existing reconstruction work of deformable 3D-GS needs input in dense state, or depends on human interaction for deformation, and does not have the ability to automatically understand deformation logic.

To sum up, the existing related techniques of digital twin construction of hinged objects cannot accurately determine the motion state of hinged objects in a case of sparse state input, and cannot accurately estimate the correct hinge logic.

Therefore, how to provide a solution to the above technical problems is a problem that needs to be solved by those skilled in prior art.

### SUMMARY

In view of the above shortcomings of the prior art, the technical problem to be solved by the present disclosure is to provide a method, a device, a terminal and a medium for constructing a digital twin model of a hinged object, which can estimate hinge logic of the hinged object with high accuracy, and can improve the geometric accuracy, visual accuracy, and the estimation accuracy of the hinged object reconstruction.

The technical schemes of the present disclosure are as follows.

A method for constructing a digital twin model of a hinged object, includes:
acquiring a first multi-view image set when a movable part in a hinged object is in an initial state before moving and a second multi-view image set when the movable part is in an end state after moving, and constructing a 3D Gaussian Splatting (3D-GS) model when the hinged object is in the initial state by using the first multi-view image set;
predicting a rigid transformation of each Gaussian point in the 3D-GS model relative to the end state by using a pre-constructed deformation network to obtain a corresponding deformed 3D-GS model, and identifying an initial movable Gaussian model corresponding to the movable part in the hinged object based on the deformed 3D-GS model; where the deformation network is a neural network obtained by self-supervised training optimization based on the second multi-view image set and the deformed 3D-GS model;
applying pre-estimated initial hinge motion parameters to the initial movable Gaussian model to optimize the initial hinge motion parameters to obtain corresponding target hinge motion parameters, and re-dividing the initial movable Gaussian model to obtain a target movable Gaussian model;
performing joint optimization operation based on the 3D-GS model, the target movable Gaussian model, and the target hinge motion parameters to construct a target 3D Gaussian digital twin model corresponding to the hinged object with the movable part and corresponding hinge logic.

In one embodiment, the predicting a rigid transformation of each Gaussian point in the 3D-GS model relative to the end state by using a pre-constructed deformation network to obtain a corresponding deformed 3D-GS model includes:
performing a preset gradient clipping operation on Gaussian point positions corresponding to the each Gaussian point in the 3D-GS model to obtain processed Gaussian point positions;
inputting the processed Gaussian point positions into the pre-constructed deformation network to obtain deformation parameters of the each Gaussian point predicted and output by the deformation network relative to the end state;
determining the corresponding deformed 3D-GS model based on the deformation parameters;
where the identifying an initial movable Gaussian model corresponding to the movable part in the hinged object based on the deformed 3D-GS model includes:
normalizing the deformation parameters correspond to the deformed 3D-GS model to obtain processed deformation parameters;
judging whether the processed deformation parameters are less than a first preset threshold;
when the processed deformation parameters are not less than the first preset threshold, determining the processed deformation parameters as target deformation parameters, and determining a Gaussian model consisting of the Gaussian points corresponding to the target deformation parameters as the initial movable Gaussian model corresponding to the movable part in the hinged object.

In one embodiment, the self-supervised training optimization based on the second multi-view image set and the deformed 3D-GS model further includes:
inputting the deformed 3D-GS model into a pre-constructed Gaussian differentiable rendering framework to obtain a corresponding first rendered image;
calculating an L₁ loss and a D_SSIM loss between the first rendered image and the first target image in a corresponding view in the second multi-view image set;
determining a corresponding first appearance loss based on the L₁ loss and the D_SSIM loss, and determining a corresponding ARAP loss;
determining a corresponding deformation loss based on the first appearance loss and the ARAP loss to make the deformation network perform self-supervised training optimization according to the deformation loss.

In one embodiment, the applying pre-estimated initial hinge motion parameters to the initial movable Gaussian model to optimize the initial hinge motion parameters to obtain corresponding target hinge motion parameters includes:
applying the pre-estimated initial hinge motion parameters to the initial movable Gaussian model to control the initial movable Gaussian model to move and deform to obtain a new deformed 3D-GS model;
inputting the new deformed 3D-GS model into the pre-constructed Gaussian differentiable rendering framework to obtain a corresponding second rendered image;
calculating a loss between the second rendered image and the second target image in a corresponding view in the second multi-view image set to obtain a corresponding second appearance loss;
determining coordinates of the Gaussian points corresponding to the new deformed 3D-GS model to obtain a first set of Gaussian point coordinates, and determining a second set of Gaussian point coordinates based on coordinates of the Gaussian points corresponding to the 3D-GS model and the deformation parameters of each Gaussian point predicted and output by the deformation network relative to the end state;
calculating a distance between the first set of Gaussian point coordinates and the second set of Gaussian point coordinates to obtain a corresponding geometric loss;
optimizing the initial hinge motion parameters based on the first appearance loss and the second appearance loss and the geometric loss to obtain the corresponding target hinge motion parameters.

In one embodiment, the performing joint optimization operation based on the 3D-GS model, the target movable Gaussian model, and the target hinge motion parameters to construct a target 3D Gaussian digital twin model corresponding to the hinged object with the movable part and corresponding hinge logic includes:
applying the target hinge motion parameters to the target movable Gaussian model to determine a state of the 3D-GS model after the target movable Gaussian model moves, and obtaining the target 3D Gaussian digital twin model corresponding to the hinged object with the movable part and corresponding hinge logic.

In one embodiment, the method for constructing a digital twin model of a hinged object further includes:
inputting a first target 3D Gaussian digital twin model when the hinged object is in the initial state into the 3D-GS model to obtain a corresponding third rendered image, and the 3D-GS model is a pre-constructed Gaussian differentiable rendering framework;
calculating a third appearance loss between the third rendered image and a third target image in a corresponding view in the first multi-view image set;
inputting a second target 3D Gaussian digital twin model when the hinged object is in the end state into the pre-constructed Gaussian differentiable rendering framework to obtain a corresponding fourth rendered image;
calculating a fourth appearance loss between the fourth rendered image and a fourth target image in a corresponding view in the second multi-view image set;
dynamically setting corresponding weights for the third appearance loss and the fourth appearance loss to obtain a first target model construction loss and a second target model construction loss;
iteratively optimizing a construction of the target 3D Gaussian digital twin model corresponding to the hinged object based on the first target model construction loss and the second target model construction loss.

In one embodiment, when the hinged object is a hinged object with multiple movable parts, the method further includes:
acquiring a third multi-view image set when another movable part in the hinged object is in the end state after moving, and determining the constructed target 3D Gaussian digital twin model corresponding to the hinged object as a new 3D-GS model when the another movable part in the hinged object is in the initial state before moving;
based on the new 3D-GS model and the third multi-view image set, re-executing a step of the predicting a rigid transformation of each Gaussian point in the 3D-GS model relative to the end state by using a pre-constructed deformation network to obtain a corresponding deformed 3D-GS model and subsequent steps, so as to construct a new target 3D Gaussian digital twin model corresponding to the hinged object with the movable part, the another movable part, and the corresponding hinge logic.

The present disclosure further provides a device for constructing a digital twin model of a hinged object, the device includes:
an image acquiring module, used for acquiring a first multi-view image set when a movable part in a hinged object is in an initial state before moving and a second multi-view image set when the movable part is in an end state after moving;
a first model-constructing module, used for constructing a 3D-GS model when the hinged object is in the initial state by using the first multi-view image set;
a model deforming module, used for predicting a rigid transformation of each Gaussian point in the 3D-GS model relative to the end state by using a pre-constructed deformation network to obtain a corresponding deformed 3D-GS model;
a movable model identifying module, used for identifying an initial movable Gaussian model corresponding to the movable part in the hinged object based on the deformed 3D-GS model; where the deformation network is a neural network obtained by self-supervised training optimization based on the second multi-view image set and the deformed 3D-GS model;
a motion parameter optimizing module, used for applying pre-estimated initial hinge motion parameters to the initial movable Gaussian model to optimize the initial hinge motion parameters to obtain corresponding target hinge motion parameters;
a movable model dividing module, used for re-dividing the initial movable Gaussian model to obtain a target movable Gaussian model;
a digital twin constructing module, used for performing joint optimization operation based on the 3D-GS model, the target movable Gaussian model, and the target hinge motion parameters to construct a target 3D Gaussian digital twin model corresponding to the hinged object with the movable part and corresponding hinge logic.

The present disclosure further provides a terminal, including: a memory, a processor, and a program of constructing a digital twin model of a hinged object stored in the memory and executed by the processor, when the program is executed by the processor, steps of the method for constructing a digital twin model of a hinged object are implemented.

The present disclosure further provides a computer-readable storage medium, where a program of constructing a digital twin model of a hinged object is stored in the computer-readable storage medium; when the program is executed by the processor, the steps of the method for constructing a digital twin model of a hinged object are implemented.

A method, a device, a terminal and a medium for constructing a digital twin model of a hinged object are provided. The method includes: acquiring a first multi-view image set when a movable part in a hinged object is in an initial state before moving and a second multi-view image set when the movable part is in an end state after moving, and constructing a 3D-GS model when the hinged object is in the initial state by using the first multi-view image set; predicting a rigid transformation of each Gaussian point in the 3D-GS model relative to the end state by using a pre-constructed deformation network to obtain a corresponding deformed 3D-GS model, and identifying an initial movable Gaussian model corresponding to the movable part in the hinged object based on the deformed 3D-GS model; where the deformation network is a neural network obtained by self-supervised training optimization based on the second multi-view image set and the deformed 3D-GS model; applying pre-estimated initial hinge motion parameters to the initial movable Gaussian model to optimize the initial hinge motion parameters to obtain corresponding target hinge motion parameters, and re-dividing the initial movable Gaussian model to obtain a target movable Gaussian model; performing joint optimization operation based on the 3D-GS model, the target movable Gaussian model, and the target hinge motion parameters to construct a target 3D Gaussian digital twin model corresponding to the hinged object with the movable part and corresponding hinge logic. In the present disclosure, based on the 3D-GS technology, the self-supervised construction of the digital twin of the hinged object is realized only by the multi-view images of the hinged object in two states, that is, based on the multi-view images of the hinged object in sparse state, the digital twin model of the hinged object is stably and high-quality reconstructed by using a completely self-supervised mode and a hierarchical optimization mode, and at the same time, the hinge logic of the movable part in the hinged object can be estimated with high accuracy, so that the geometric accuracy, visual accuracy and the estimation accuracy of the hinged object reconstruction can be improved.

### BRIEF DESCRIPTION OF THE DRAWINGS

FIG. 1 is a flowchart diagram of an embodiment of a method for constructing a digital twin model of a hinged object in the present disclosure.

FIG. 2 is a schematic diagram of a deformation field estimation process disclosed in the present disclosure.

FIG. 3 is a schematic diagram of a self-supervised hinged object reconstruction disclosed in the present disclosure.

FIG. 4 is a schematic diagram of a multi movable part reconstruction.

FIG. 5 is a schematic diagram of effects contrast.

FIG. 6 is a schematic diagram of an embodiment of a method for constructing a digital twin model of a hinged object in the present disclosure.

FIG. 7 is a schematic diagram of an embodiment of a terminal in the present disclosure.

### DETAILED DESCRIPTION OF EMBODIMENTS

In order to make the purposes, technical schemes, and effects of the present disclosure more clear and definite, the present disclosure is further described in detailed reference to the accompanying drawings and embodiments. It should be understood that the specific embodiments described herein are only used to explain the present disclosure, not to limit the present disclosure.

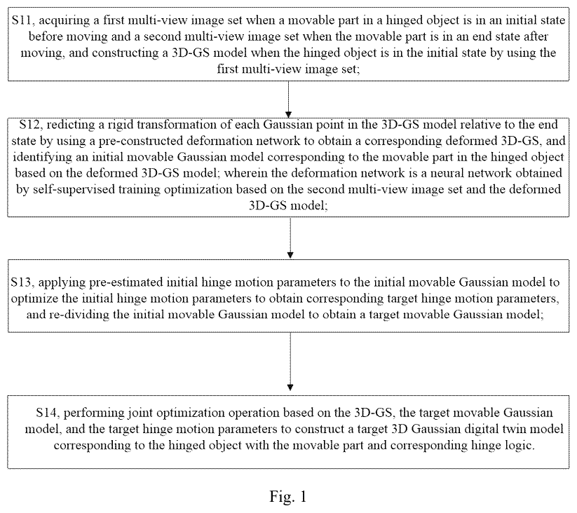

As shown in FIG. 1, which is a flowchart diagram of an embodiment of a method for constructing a digital twin model of a hinged object in the present disclosure. As shown in FIG. 1, the method for constructing a digital twin model of a hinged object, including:

S11, acquiring a first multi-view image set when a movable part in a hinged object is in an initial state before moving and a second multi-view image set when the movable part is in an end state after moving, and constructing a 3D-GS model when the hinged object is in the initial state by using the first multi-view image set;

In the embodiment, acquiring multi-view images of the hinged object in two states l₀, and l₁, to obtain corresponding image sets, that is, acquiring a first multi-view image set when one movable part in the hinged object is in an initial state l₀ before moving and a second multi-view image set when the one movable part is in an end state l₀ after moving. Then constructing the 3D-GS model when the hinged object is in the initial state by using the first multi-view image set. The 3D-GS model can be used as an underlying expression, micro-rendering and explicit expression of the 3D-GS model can improve efficiency of training and rendering quality from a new perspective.

It should be pointed out that the self-supervised reconstruction of hinged objects only needs multi-view pictures of two states before and after the hinge structure changes, which is in line with the behavior pattern of hinged object reconstruction in daily life. Hinge objects mainly include two types of hinged objects, one is translational hinged objects, such as drawers and paper cutters, and the other is rotational hinged objects, such as refrigerators, ovens and notebook computers, and the hinge principle of the former is that the moving parts translate along a certain direction a in a 3D space, while the latter is that the moving parts rotate along an axis in the space, where the axis is determined by a point p in the space.

S12, predicting a rigid transformation of each Gaussian point in the 3D-GS model relative to the end state by using a pre-constructed deformation network to obtain a corresponding deformed 3D-GS model, and identifying an initial movable Gaussian model corresponding to the movable part in the hinged object based on the deformed 3D-GS model; where the deformation network is a neural network obtained by self-supervised training optimization based on the second multi-view image set and the deformed 3D-GS model;

In the embodiment, predicting the rigid transformation of each Gaussian point in the 3D-GS model relative to the end state by using the pre-constructed deformation network to obtain the corresponding deformed 3D-GS model, and then identifying the initial movable Gaussian model corresponding to the movable part in the hinged object based on the deformed 3D-GS model. Specifically, performing a preset gradient clipping operation on Gaussian point positions corresponding to the each Gaussian point in the 3D-GS model to obtain processed Gaussian point positions; inputting the processed Gaussian point positions into the pre-constructed deformation network to obtain deformation parameters of the each Gaussian point predicted and output by the deformation network relative to the end state; determining the corresponding deformed 3D-GS model based on the deformation parameters; normalizing the deformation parameters correspond to the deformed 3D-GS model to obtain processed deformation parameters; judging whether the processed deformation parameters are less than a first preset threshold; when the processed deformation parameters are not less than the first preset threshold, the processed deformation parameters are determined as target deformation parameters, and a Gaussian model consisting of the Gaussian points corresponding to the target deformation parameters is determined as the initial movable Gaussian model corresponding to the movable part in the hinged object. Understandably, the pre-constructed deformation network is obtained by using the second multi-view image set in the pre-trained deformation network, and then the deformation parameters of the relative end state of each Gaussian point in the 3D-GS model are predicted through the deformation network, so as to determine the deformed 3D-GS model. Furthermore, based on the deformation parameters, the movable part of the hinged object can also be identified, that is, the movable Gaussian part in the 3D-GS model can be identified to obtain the initial movable Gaussian model. That is to say, the deformation network is used to predict a deformation field of the 3D-GS model, and then the initial movable area on the 3D-GS model can be roughly identified, where the deformation parameters can include translational motion parameters and rotational motion parameters. For the deformed 3D-GS model, the movement types can also be classified according to the degree of deformation to determine whether the movable part in the deformed 3D-GS model is a translation hinge structure or a rotation hinge structure.

It should be pointed out that the roughly identified initial movable area (initial movable Gaussian model) does not need to be very accurate, because the pre-estimated motion parameters can be further refined in the subsequent joint optimization, and the initial movable Gaussian model can provide a good approximation for the subsequent joint optimization as initialization.

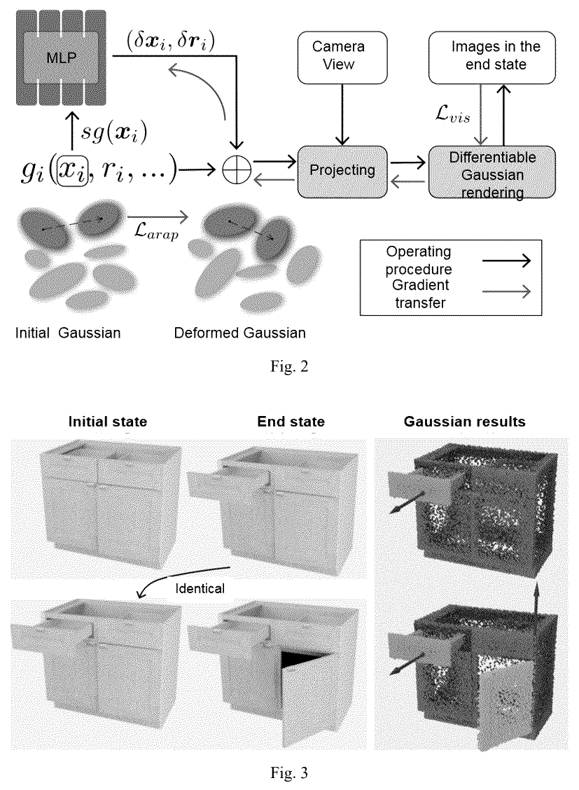

For example, as shown in FIG. 2, the deformation network takes the position xᵢ of each Gaussian point of the 3D-GS model as input, and outputs δₓ_{ᵢ} and δᵣ_{ᵢ} corresponding to each predicted Gaussian point, that is:

$$( {δ}_{{x}_{i}} , {δ}_{{r}_{i}} ) = {f}_{θ} ( s g ( {x}_{i} ) ) ,$$

where δₓ_{ᵢ} represents the translation of Gaussian gᵢ, and δᵣ_{ᵢ} represents the rotation of Gaussian gᵢ.

It should be pointed out that in order to predict the deformation field without changing the original position of the each Gaussian point, a gradient clipping operation sg(⋅) can be added to the position xᵢ, and a network architecture of the deformation network can be a Multi-Layer Perceptron (MLP), such as a four-layer perceptron, and it can also be a neural network with other structures, or a heuristic method such as simulated annealing.

In the process of identifying the movable Gaussian part in the 3D-GS model, the displacement ∥δx∥₂ and rotation ∥δr∥₂ are normalized to between 0 and 1, and the Gaussian part of ∥δx∥₂≥θ or ∥δr∥₂>θ is determined as the movable Gaussian model Gₘ.

It should be pointed out that choosing a lower first preset threshold θ usually contains a static Gaussian part, which may lead to suboptimal results in the subsequent optimization of motion parameters. Therefore, the initial movable Gaussian model can be obtained by setting a higher first preset threshold θ to obtain a Gaussian part with higher confidence, which can be used to predict the motion parameters of the whole part. For example, setting the first preset threshold θ to 0.3 can be used as a threshold to identify whether the Gaussian part composed of Gaussian points is a movable Gaussian part.

Moreover, in the process of realizing the self-supervised training optimization of the deformation network by the end state l₁ supervision, the step further specifically includes: inputting the deformed 3D-GS model into a pre-constructed Gaussian differentiable rendering framework to obtain a corresponding first rendered image; calculating an L₁ loss and a D_SSIM loss between the first rendered image and the first target image in a corresponding view in the second multi-view image set; determining a corresponding first appearance loss based on the L₁ loss and the D_SSIM loss, and determining a corresponding ARAP loss; determining a corresponding deformation loss based on the first appearance loss and the ARAP loss to make the deformation network perform self-supervised training optimization according to the deformation loss.

For instance, inputting the deformed 3D-GS model into the Gaussian differentiable rendering framework to obtain the rendered image, and then calculating an L₁ loss and a D_SSIM loss between the rendered image and the image in a corresponding view in the end state l₁, further processing the L₁ loss and the D_SSIM loss by linear combination to obtain the corresponding first appearance loss (gradient error), that is:

$${L}_{app} = ( 1 − λ ) {L}_{1} + λ {L}_{D \_ SSIM} ,$$

where Lₐₚₚ represents the first appearance loss, L₁ represents the L₁ loss, L_{D_SSIM} represents the D_SSIM loss, λ represents a weight corresponding to the D_SSIM loss, and 1−λ represents a weight corresponding to L₁ loss.

It should be pointed out that deformations are locally rigid based on prior knowledge, therefore an additional ARAP (As-Rigid-As-Possible) loss Lₐᵣₐₚ, that is, a regularized loss function for learning the deformable shape generator, is added to encourage the movement of each Gaussian point to maintain local rigidity, where the ARAP loss is Lₐᵣₐₚ:

$${L}_{arap} = \frac{1}{k \cdot S} {\sum }_{i ∈ S} {\sum }_{j ∈ {knn}_{i , k}} {L}_{arap}^{i , j} ,$$

$${L}_{arap}^{i , j} = {ω}_{i , j} {‖ ( {x}_{j} − {x}_{i} ) − {R}_{i} {\hat{R}}_{i}^{- 1} ( {\hat{x}}_{j} − {\hat{x}}_{i} ) ‖}_{2} ,$$

$${ω}_{i , j} = exp ( − {λ}_{ω} {‖ {x}_{j} − {x}_{i} ‖}_{2}^{2} ) ,$$

where S represents a quantity of Gauss, knn_{i,k} represents the k nearest Gauss around Gauss i, which k can be set to 20,

$${L}_{arap}^{i , j}$$

represents the ARAP loss function between Gauss i and Gauss j, ω_{i,j} represents the weight factor of Gauss pair, xⱼ represents the 3D coordinates of Gauss j, xᵢ represents the 3D coordinates of Gauss i, Rᵢ represents the rotation matrix of Gauss i relative to a world coordinate, \hat{x}ᵢ represents the 3D coordinates of Gauss i after deformation to the end state, \hat{x}ⱼ represents the 3D coordinates of Gauss j after deformation to the end state, \hat{R}ᵢ represents after Gaussian i deformation to the end state relative to the world coordinate, λ_{ω} represents a hyperparameter and can be set to 20.

Therefore, a final deformation loss is determined based on the first appearance loss and the ARAP loss, and then the final deformation loss is transmitted back to the deformation network to realize self-supervised training and learning, such as processing the first appearance loss and the ARAP loss by linear combination to obtain the deformation loss, that is:

$${L}_{deform} - {L}_{app} + {λ}_{arap} {L}_{arap} ,$$

where a weighting λₐᵣₐₚ corresponding to the ARAP loss can be set to 1.

S13, applying pre-estimated initial hinge motion parameters to the initial movable Gaussian model to optimize the initial hinge motion parameters to obtain corresponding target hinge motion parameters, and re-dividing the initial movable Gaussian model to obtain a target movable Gaussian model.

In the embodiment, after identifying the movable Gaussian part in the 3D-GS model to obtain the initial movable Gaussian model Gₘ, the predicted motion parameters can be optimized by applying the global rigid transformation to the initial movable Gaussian model Gₘ, and the movable Gaussian part can deform with the motion parameters, so as to obtain more accurate motion parameters by maintaining a basic principle of visual and geometric consistency between the two states. Specifically, step of S13 includes: applying the pre-estimated initial hinge motion parameters to the initial movable Gaussian model to control the initial movable Gaussian model to move and deform to obtain a new deformed 3D-GS model; inputting the new deformed 3D-GS model into the pre-constructed Gaussian differentiable rendering framework to obtain a corresponding second rendered image; calculating a loss between the second rendered image and the second target image in a corresponding view in the second multi-view image set to obtain a corresponding second appearance loss; determining coordinates of the Gaussian points corresponding to the new deformed 3D-GS model to obtain a first set of Gaussian point coordinates, and determining a second set of Gaussian point coordinates based on coordinates of the Gaussian points corresponding to the 3D-GS model and the deformation parameters of each Gaussian point predicted and output by the deformation network relative to the end state; calculating a distance between the first set of Gaussian point coordinates and the second set of Gaussian point coordinates to obtain a corresponding geometric loss; optimizing the initial hinge motion parameters based on the first appearance loss and the second appearance loss and the geometric loss to obtain the corresponding target hinge motion parameters.

It should be pointed out that when the translational motion is fitted with the rotational motion parameters, an axis of the rotational motion parameters is usually very far from the object to ensure that the movable Gaussian part moves in a nearly translational manner during the motion. Therefore, in the 3D-GS model, the movable Gaussian part changes in rotation, and a fulcrum |p| is greater than a spatial radius R, and the motion is considered to be translational, so the optimization parameters and motion function are reinitialized to adapt to the translational motion, where R can be set to 4.

In the embodiment, the target movable Gaussian model is obtained by re-dividing the initial movable Gaussian model. Understandably, the Gaussian of moving parts is re-divided to obtain more stringent dividing results of moving parts on the Gaussian model for joint optimization. For example, a second preset threshold with a smaller value, such as τ=0.1, can be used to re-dividing the movable Gaussian part in the 3D-GS model, so as to obtain a stricter segmentation of the movable Gaussian part and a more accurate segmentation result, that is, the target movable Gaussian model.

S14, performing joint optimization operation based on the 3D-GS model, the target movable Gaussian model, and the target hinge motion parameters to construct a target 3D Gaussian digital twin model corresponding to the hinged object with the movable part and corresponding hinge logic.

In the embodiment, obtaining the 3D-GS model, the target movable Gaussian model, and the target hinge motion parameters, and finding an optimal value by joint optimization. Specifically, applying the target hinge motion parameters to the target movable Gaussian model to determine a state of the 3D-GS model after the target movable Gaussian model moves, and obtaining the target 3D Gaussian digital twin model corresponding to the hinged object with the movable part and corresponding hinge logic. Understandably, applying the more accurate target hinge motion parameters to the target movable Gaussian model to obtain the corresponding state of the target movable Gaussian model after moving. While for the immobile part on the 3D-GS model, the start state and the end state are identical.

It should be pointed out that after constructing the target 3D Gaussian digital twin when the hinged object is in the end state, further includes equipping with high-quality colored appearance for the target 3D Gaussian digital twin, so as to play more roles in downstream applications, for example, it can be transferred from the simulator to the real-world embodied intelligence during training.

It should also be pointed out that in a process of Gaussian densification and deletion, a classification inaccuracy in the two masks can be regarded as Gaussian noise, which are automatically updated with the process of Gaussian densification and deletion, thus achieving accurate segmentation results of movable parts. Moreover, because only using the initial state to supervise the optimization of Gaussian may lead to a problem that Gaussian distribution is over-fitted to the initial state, the weights of loss functions on the initial state and the end state can be dynamically set to prevent the final Gaussian distribution from over-fitting to the initial state. Specifically, the step includes: inputting a first target 3D Gaussian digital twin model when the hinged object is in the initial state into the 3D-GS model to obtain a corresponding third rendered image, and the 3D-GS model is a pre-constructed Gaussian differentiable rendering framework; calculating a third appearance loss between the third rendered image and a third target image in a corresponding view in the first multi-view image set; inputting a second target 3D Gaussian digital twin model when the hinged object is in the end state into the pre-constructed Gaussian differentiable rendering framework to obtain a corresponding fourth rendered image; calculating a fourth appearance loss between the fourth rendered image and a fourth target image in a corresponding view in the second multi-view image set; dynamically setting corresponding weights for the third appearance loss and the fourth appearance loss to obtain a first target model construction loss and a second target model construction loss; iteratively optimizing a construction of the target 3D Gaussian digital twin model corresponding to the hinged object based on the first target model construction loss and the second target model construction loss.

For instance, a weight of the third appearance loss

$${L}_{app}^{0}$$

is defined as ω⁰, a weight of the forth appearance loss

$${L}_{app}^{1}$$

is defined as ω¹, where your ω⁰ and ω¹ can be set to 0.5, that is ω⁰=ω¹=0.5.

Furthermore, when the hinged object is a hinged object with multiple movable parts, the method further includes: acquiring a third multi-view image set when another movable part in the hinged object is in an end state after moving, and determining the constructed target 3D Gaussian digital twin model corresponding to the hinged object as a new 3D-GS model when the another movable part in the hinged object is in the initial state before moving; based on the new 3D-GS model and the third multi-view image set, re-executing a step of the predicting a rigid transformation of each Gaussian point in the 3D-GS model relative to the end state by using a pre-constructed deformation network to obtain a corresponding deformed 3D-GS model and subsequent steps, so as to construct a new target 3D Gaussian digital twin model corresponding to the hinged object with the movable part, the another movable part, and the corresponding hinge logic.

Understandably, the process of reconstructing the hinged object with multiple movable parts includes: the whole reconstruction process is decomposed into several subprocesses of single object modeling, and each subprocess is solved in turn, that is, the hinged object with multiple movable parts is gradually reconstructed by dividing subtasks. As shown in FIG. 3, in the whole reconstruction process, a same set of Gaussian distributions is always maintained, and the initial state of the subsequent sub-process is aligned with a certain state of the previous sub-process, so as to ensure that only one new movable part is introduced in the new sub-process. Before entering the next sub-process, the movable part in the current Gaussian distribution is configured to the initial state of the subsequent sub-process, and in each sub-process, the movable mask can be marked with a new identifier, and meanwhile the immovable Gaussian distribution can be optimized to update the new movable mask. Because the movable mask can be densified and pruned at the same time with the Gaussian distribution, and the Gaussian distribution marked by the movable mask in the previous sub-process can also be optimized in the next new sub-process, for the new sub-process, the step of pre-training the initial Gaussian distribution can be skipped and the deformation network can be directly entered.

It can be seen that in the embodiment of the present disclosure, based on the 3D-GS technology, the self-supervised construction of the digital twin of the hinged object is realized only by the multi-view images of the hinged object in two states, that is, based on the multi-view images of the hinged object in sparse state, the digital twin model of the hinged object is stably and high-quality reconstructed by using a completely self-supervised mode and a hierarchical optimization mode, and at the same time, the hinge logic of the movable part in the hinged object can be estimated with high accuracy, so that the geometric accuracy, visual accuracy and the estimation accuracy of the hinged object reconstruction can be improved.

It should be pointed out that optimizing the motion parameters, movable Gaussian model (movable area) and Gaussian representation (appearance) at the same time has a problem of tending to find the local optimal solution or facing calculation failure, that is, the rigid body transformation of the movable parts of the object according to the motion parameters can greatly affect the learning of the geometric shape and visual appearance of the movable parts, and vice versa, the optimization of the movable parts and motion parameters may be significantly affected by the rendering quality. Therefore, it is very difficult to optimize the geometric shape, appearance and motion parameters of the object as a whole. Therefore, the overall goal can be handled step by step, and each step aims to obtain the initial parameter estimation close to the real value, thus improving the possibility of reaching the optimal solution.

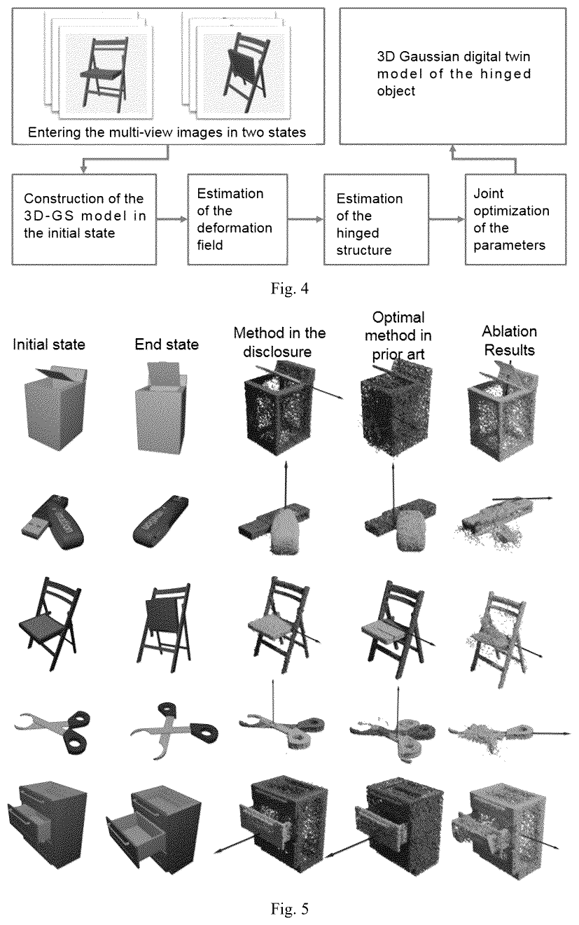

By using 3D-GS technology as the carrier to construct digital twin of hinged objects, self-supervised training can avoid the limitation of the method to the prior object types, that is, by obtaining multi-view RGB views of hinged objects in two states, can estimate the moving parts and hinge motion parameters of hinged objects by self-supervised without any prior knowledge, and at the same time construct 3D-GS digital twin of objects to achieve the purpose of new-view synthesis. For instance, as shown in FIG. 4, determining two states l₀, and l₁ of the hinged object; firstly, training a static Gaussian model by only using the multi-view images in the first state l₀ and then the deformation field estimation is realized. The deformation field of the 3D-GS model is estimated by using the deformation network under the supervision of the multi-view images in the second state l₁, and the motion parameters are not directly optimized. Then entering a process of hinge structure estimation. That is, once the deformation field of the 3D-GS model is obtained, the movable parts on the 3D-GS model can be roughly identified, and the hinge motion parameters according to the deformation can be estimated. Then based on the deformation, the hinge motion parameters are estimated, and then the rigid motion is projected to the movable Gaussian model to optimize the hinge motion parameters to obtain the target hinge motion parameters, and the roughly identified movable part on the 3D-GS model is re-divided to obtain more accurate segmentation results. Finally, performing joint optimization on the representation of the Gaussian model, the segmentation results, and the target hinge motion parameters to obtain the final reconstruction result of the hinged object and accurate hinge logic.

By using an open source algorithm to carry out experiments on the published PARIS data, and selecting several objects from PartNet data set to make the data set for experiments, as shown in FIG. 5, the results show that the technical scheme of the present disclosure has obviously improved the geometric accuracy, visual accuracy and estimation accuracy of hinge structure of reconstruction, and has also obtained a realistic effect by constructing real-life objects as experimental verification, and training efficiency is also higher than the traditional method.

Furthermore, the application scenarios of the technical scheme of the present disclosure can include but not limited to a reconstruction of the hinge structure of a single human joint, a reconstruction of the hinge structure of a mechanical arm, etc.

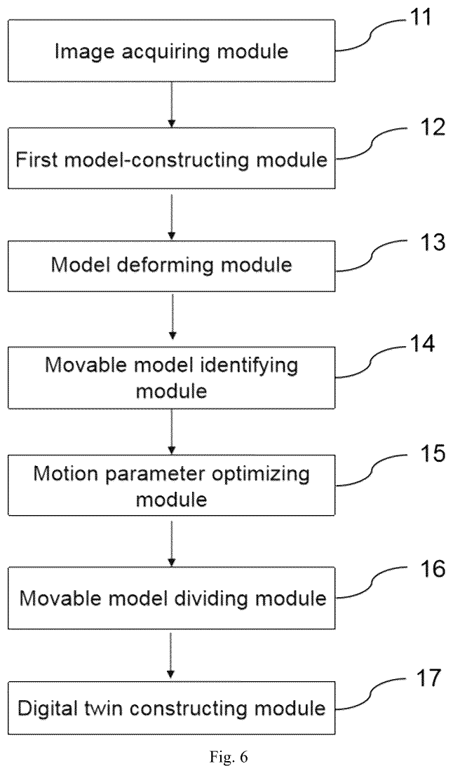

In one embodiment, as shown in FIG. 6, based on the method for constructing a digital twin model of a hinged object, the present disclosure further provides a device for constructing a digital twin model of a hinged object, including:
an image acquiring module 11, used for acquiring a first multi-view image set when a movable part in a hinged object is in an initial state before moving and a second multi-view image set when the movable part is in an end state after moving;
a first model-constructing module 12, used for constructing a 3D-GS model when the hinged object is in the initial state by using the first multi-view image set;
a model deforming module 13, used for predicting a rigid transformation of each Gaussian point in the 3D-GS model relative to the end state by using a pre-constructed deformation network to obtain a corresponding deformed 3D-GS model;
a movable model identifying module 14, used for identifying an initial movable Gaussian model corresponding to the movable part in the hinged object based on the deformed 3D-GS model; where the deformation network is a neural network obtained by self-supervised training optimization based on the second multi-view image set and the deformed 3D-GS model;
a motion parameter optimizing module 15, used for applying pre-estimated initial hinge motion parameters to the initial movable Gaussian model to optimize the initial hinge motion parameters to obtain corresponding target hinge motion parameters a movable model dividing module 16, used for re-dividing the initial movable Gaussian model to obtain a target movable Gaussian model;
a digital twin constructing module 17, used for performing joint optimization operation based on the 3D-GS model, the target movable Gaussian model, and the target hinge motion parameters to construct a target 3D Gaussian digital twin model corresponding to the hinged object with the movable part and corresponding hinge logic. FIG. 11 is a functional principle block diagram of an embodiment of a terminal in the present disclosure. The terminal may include:

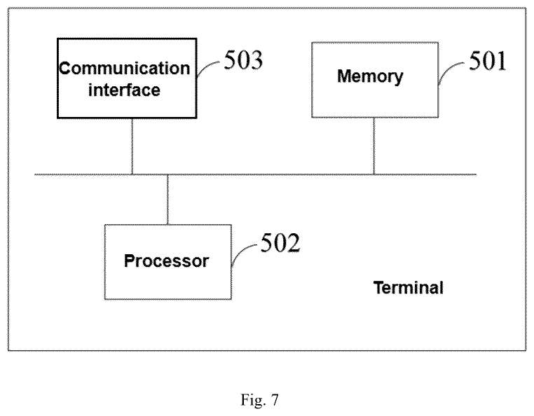

FIG. 7 is a schematic diagram of an embodiment of a terminal in the present disclosure. The terminal can include:
a memory 501, a processor 502, and a program of reconstructing surface from point clouds based on parametric representation stored in the memory 501 and executed by the processor 502.

When the program is executed by the processor 502, steps of the method for constructing a digital twin model of a hinged object are implemented.

Furthermore, the terminal includes:
a communication interface 503 for communication in the memory 501 and the processor 502.

The memory 501 is used for storing computer programs that can run on the processor 502.

The memory 501 may include a high-speed RAM memory or a non-volatile memory, such as at least one disk memory.

If the memory 501, the processor 502, and the communication interface 503 are independently realized, the communication interface 503, the memory 501, and the processor 502 can be connected to each other by a bus and complete communication with each other. The bus can be an Industry Standard Architecture (ISA) bus, a Periphera 1 part (PCI) bus or an Extended Industry Standard Architecture (EISA) bus. The bus can be divided into address bus, data bus and control bus. For the convenience of representation, only one line is shown in the figure, but it does not mean that there is only one bus or one type of bus.

Alternatively, if the memory 501, the processor 502 and the communication interface 503 are integrated on one chip, the memory 501, the processor 502 and the communication interface 503 can communicate with each other through an internal interface.

The processor 502 may be a Central Processing Unit (CPU), or an present disclosure specific integrated circuit (ASIC), or one or more integrated circuits configured to implement the embodiments of the present disclosure.

A computer-readable storage medium is also provided in the embodiment, on which a computer program is stored. When executed by a processor, the computer program realizes the method for constructing a digital twin model of a hinged object.

In the description of the specification, descriptions referring to the terms “one embodiment”, “some embodiments”, “examples”, “specific examples” or “some examples” mean that specific features, structures, materials or characteristics described in connection with the embodiment or example are included in at least one embodiment or example of the present disclosure. In the specification, the schematic representations of the above terms are not necessarily aimed at the same embodiment or example. Moreover, the specific features, structures, materials or characteristics described can be combined in any one or n embodiments or examples in a suitable way. In addition, those skilled in the art can combine and combine different embodiments or examples and features of different embodiments or examples described in the specification without contradicting each other.

In addition, the terms “first” and “second” are only used for descriptive purposes, and cannot be understood as indicating or implying relative importance or implicitly indicating the quantity of indicated technical features. Therefore, the features defined as “first” and “second” can explicitly or implicitly include at least one of these features. In the description of the present disclosure, the meaning of “N” is at least two, such as two, three, etc., unless otherwise specifically defined.

Any process or method description in the flowchart or otherwise described herein can be understood as representing a module, segment or part of code that includes one or n executable instructions for implementing customized logic functions or steps of the process, and the scope of embodiments of the present disclosure includes other implementations, in which functions can be performed out of the order shown or discussed, including in a substantially simultaneous manner or in the reverse order according to the functions involved, which should be understood by those skilled in prior art to which the embodiments of the present disclosure belong.

The logic and/or steps represented in the flowchart or described in other ways herein, for example, can be regarded as a sequenced list of executable instructions for realizing logical functions, and can be embodied in any computer-readable medium for use by or in combination with an instruction execution system, apparatus or equipment (such as a computer-based system, a system including a processor or other systems that can read and execute instructions from the instruction execution system, apparatus or equipment). For the purposes of this specification, a “computer-readable medium” can be any device that can contain, store, communicate, propagate or transmit a program for use by or in connection with an instruction execution system, device or device. More specific examples (non-exhaustive list) of computer-readable media include the following: an electrical connection part (electronic device) with one or n wires, a portable computer disk box (magnetic device), a random access memory (RAM), a read-only memory (ROM), an erasable and editable read-only memory (EPROM or flash memory), an optical fiber device, and a portable CD-ROM. In addition, the computer-readable medium can even be paper or other suitable medium on which the program can be printed, because the program can be electronically obtained by optically scanning the paper or other medium, followed by editing, interpreting or otherwise processing if necessary, and then stored in the computer memory.

It should be understood that various parts of the present disclosure can be implemented in hardware, software, firmware, or a combination thereof. In the above embodiments, n steps or methods can be realized by software or firmware stored in a memory and executed by an appropriate instruction execution system. If it is realized by hardware, as in another embodiment, it can be realized by any one of the following technologies known in the art or their combination: discrete logic circuits with logic gates for realizing logic functions on data signals, application specific integrated circuits with appropriate combinational logic gates, programmable gate arrays (PGA), field programmable gate arrays (FPGA), etc.

Those skilled in the art can understand that all or part of the steps carried by the method of the above embodiment can be completed by instructing related hardware through a program, which can be stored in a computer-readable storage medium, and the program, when executed, includes one or a combination of the steps of the method embodiment.

In addition, each functional unit in each embodiment of the present disclosure can be integrated in one processing module, or each unit can exist physically alone, or two or more units can be integrated in one module. The above integrated modules can be realized in the form of hardware or software functional modules. Integrated modules can also be stored in a computer-readable storage medium if they are implemented in the form of software functional modules and sold or used as independent products.

The storage medium mentioned above can be read-only memory, magnetic disk or optical disk, etc. Although the embodiments of the present disclosure have been shown and described above, it can be understood that the above embodiments are exemplary and cannot be understood as limitations of the present disclosure, and those skilled in the art can make changes, modifications, substitutions and variations to the above embodiments within the scope of the present disclosure.

It should be understood that the present disclosure is not limited to the above embodiments, and those skilled in the art can make improvements or transformations according to the above descriptions, and all these improvements and transformations should belong to the protection scope of the appended claims of the present disclosure.

What is claimed is:

1. A method for constructing a digital twin model of a hinged object, the method comprising:
acquiring a first multi-view image set when a movable part in a hinged object is in an initial state before moving and a second multi-view image set when the movable part is in an end state after moving, and constructing a 3D-GS model when the hinged object is in the initial state by using the first multi-view image set;
predicting a rigid transformation of each Gaussian point in the 3D-GS model relative to the end state by using a pre-constructed deformation network to obtain a corresponding deformed 3D-GS model, and identifying an initial movable Gaussian model corresponding to the movable part in the hinged object based on the deformed 3D-GS model; wherein the deformation network is a neural network obtained by self-supervised training optimization based on the second multi-view image set and the deformed 3D-GS model;
applying pre-estimated initial hinge motion parameters to the initial movable Gaussian model to optimize the initial hinge motion parameters to obtain corresponding target hinge motion parameters, and re-dividing the initial movable Gaussian model to obtain a target movable Gaussian model; and
performing joint optimization operation based on the 3D-GS model, the target movable Gaussian model, and the target hinge motion parameters to construct a target 3D Gaussian digital twin model corresponding to the hinged object with the movable part and corresponding hinge logic.

2. The method for constructing a digital twin model of a hinged object according to claim 1, wherein the predicting a rigid transformation of each Gaussian point in the 3D-GS model relative to the end state by using a pre-constructed deformation network to obtain a corresponding deformed 3D-GS model comprises:
performing a preset gradient clipping operation on Gaussian point positions corresponding to each Gaussian point in the 3D-GS model to obtain processed Gaussian point positions;
inputting the processed Gaussian point positions into the pre-constructed deformation network to obtain deformation parameters of each Gaussian point predicted and output by the deformation network relative to the end state;
determining the corresponding deformed 3D-GS model based on the deformation parameters;
wherein the identifying an initial movable Gaussian model corresponding to the movable part in the hinged object based on the deformed 3D-GS model comprises:
normalizing the deformation parameters correspond to the deformed 3D-GS model to obtain processed deformation parameters;
judging whether the processed deformation parameters are less than a first preset threshold; and
when the processed deformation parameters are not less than the first preset threshold, determining the processed deformation parameters as target deformation parameters, and determining a Gaussian model consisting of the Gaussian points corresponding to the target deformation parameters as the initial movable Gaussian model corresponding to the movable part in the hinged object.

3. The method for constructing a digital twin model of a hinged object according to claim 2, wherein the self-supervised training optimization based on the second multi-view image set and the deformed 3D-GS model further comprises:
inputting the deformed 3D-GS model into a pre-constructed Gaussian differentiable rendering framework to obtain a corresponding first rendered image;
calculating an L₁ loss and a D_SSIM loss between the first rendered image and the first target image in a corresponding view in the second multi-view image set;
determining a corresponding first appearance loss based on the L₁ loss and the D_SSIM loss, and determining a corresponding ARAP loss; and
determining a corresponding deformation loss based on the first appearance loss and the ARAP loss to make the deformation network perform self-supervised training optimization according to the deformation loss.

4. The method for constructing a digital twin model of a hinged object according to claim 3, wherein the applying pre-estimated initial hinge motion parameters to the initial movable Gaussian model to optimize the initial hinge motion parameters to obtain corresponding target hinge motion parameters comprises:
applying the pre-estimated initial hinge motion parameters to the initial movable Gaussian model to control the initial movable Gaussian model to move and deform to obtain a new deformed 3D-GS model;
inputting the new deformed 3D-GS model into the pre-constructed Gaussian differentiable rendering framework to obtain a corresponding second rendered image;
calculating a loss between the second rendered image and the second target image in a corresponding view in the second multi-view image set to obtain a corresponding second appearance loss;
determining coordinates of the Gaussian points corresponding to the new deformed 3D-GS model to obtain a first set of Gaussian point coordinates, and determining a second set of Gaussian point coordinates based on coordinates of the Gaussian points corresponding to the 3D-GS model and the deformation parameters of each Gaussian point predicted and output by the deformation network relative to the end state;
calculating a distance between the first set of Gaussian point coordinates and the second set of Gaussian point coordinates to obtain a corresponding geometric loss; and
optimizing the initial hinge motion parameters based on the first appearance loss and the second appearance loss and the geometric loss to obtain the corresponding target hinge motion parameters.

5. The method for constructing a digital twin model of a hinged object according to claim 1, wherein the performing joint optimization operation based on the 3D-GS model, the target movable Gaussian model, and the target hinge motion parameters to construct a target 3D Gaussian digital twin model corresponding to the hinged object with the movable part and corresponding hinge logic comprises:
applying the target hinge motion parameters to the target movable Gaussian model to determine a state of the 3D-GS model after the target movable Gaussian model moves and obtaining the target 3D Gaussian digital twin model corresponding to the hinged object with the movable part and corresponding hinge logic.

6. The method for constructing a digital twin model of a hinged object according to claim 1, further comprising:
inputting a first target 3D Gaussian digital twin model when the hinged object is in the initial state into the 3D-GS model to obtain a corresponding third rendered image, and the 3D-GS model is a pre-constructed Gaussian differentiable rendering framework;
calculating a third appearance loss between the third rendered image and a third target image in a corresponding view in the first multi-view image set;
inputting a second target 3D Gaussian digital twin model when the hinged object is in the end state into the pre-constructed Gaussian differentiable rendering framework to obtain a corresponding fourth rendered image;
calculating a fourth appearance loss between the fourth rendered image and a fourth target image in a corresponding view in the second multi-view image set;
dynamically setting corresponding weights for the third appearance loss and the fourth appearance loss to obtain a first target model construction loss and a second target model construction loss; and
iteratively optimizing a construction of the target 3D Gaussian digital twin model corresponding to the hinged object based on the first target model construction loss and the second target model construction loss.

7. The method for constructing a digital twin model of a hinged object according to claim 1, wherein when the hinged object is a hinged object with multiple movable parts, the method further comprises:
acquiring a third multi-view image set when another movable part in the hinged object is in the end state after moving, and determining the constructed target 3D Gaussian digital twin model corresponding to the hinged object as a new 3D-GS model when the another movable part in the hinged object is in the initial state before moving; and
based on the new 3D-GS model and the third multi-view image set, re-executing a step of the predicting a rigid transformation of each Gaussian point in the 3D-GS model relative to the end state by using a pre-constructed deformation network to obtain a corresponding deformed 3D-GS model and subsequent steps, so as to construct a new target 3D Gaussian digital twin model corresponding to the hinged object with the movable part, the another movable part, and the corresponding hinge logic.

8. A device for constructing a digital twin model of a hinged object, wherein the device comprises:
an image acquiring module, used for acquiring a first multi-view image set when a movable part in a hinged object is in an initial state before moving and a second multi-view image set when the movable part is in an end state after moving;
a first model-constructing module, used for constructing a 3D-GS model when the hinged object is in the initial state by using the first multi-view image set;
a model deforming module, used for predicting a rigid transformation of each Gaussian point in the 3D-GS model relative to the end state by using a pre-constructed deformation network to obtain a corresponding deformed 3D-GS model;
a movable model identifying module, used for identifying an initial movable Gaussian model corresponding to the movable part in the hinged object based on the deformed 3D-GS model; wherein the deformation network is a neural network obtained by self-supervised training optimization based on the second multi-view image set and the deformed 3D-GS model;
a motion parameter optimizing module, used for applying pre-estimated initial hinge motion parameters to the initial movable Gaussian model to optimize the initial hinge motion parameters to obtain corresponding target hinge motion parameters;
a movable model dividing module, used for re-dividing the initial movable Gaussian model to obtain a target movable Gaussian model; and
a digital twin constructing module, used for performing joint optimization operation based on the 3D-GS model, the target movable Gaussian model, and the target hinge motion parameters to construct a target 3D Gaussian digital twin model corresponding to the hinged object with the movable part and corresponding hinge logic.

9. A terminal, comprising: a memory, a processor, and a program of constructing a digital twin model of a hinged object stored in the memory and executed by the processor, when the program is executed by the processor, steps of the method for constructing a digital twin model of a hinged object according to claim 1 are implemented.
